(19) United States
(12) Patent Application Publication
(10) Pub. No.: US 2010/0165166 A1
(43) Pub. Date: Jul. 1, 2010

(54) SOLID-STATE IMAGING DEVICE

(75) Inventors: Hiroshi Hara, Hyogo (JP); Yoshiaki Kato, Shiga (JP)

Correspondence Address: GREENBLUM & BERNSTEIN, P.L.C., 1950 ROLAND CLARKE PLACE, RESTON, VA, 20191, US

(73) Assignee: PANASONIC CORPORATION, Osaka (JP)

(21) Appl. No.: 12/601,109

(22) PCT Filed: May 28, 2008
(86) PCT No.: PCT/JP2008/001326

§ 371 Date: Nov. 20, 2009

(30) Foreign Application Priority Data
Jun. 8, 2007 (JP) 2007-152946
Oct. 2, 2007 (JP) 2007-259244

(51) Int. Cl. H04N 5/335

(52) U.S. Cl. 348/311; 348/E05.091

(57) ABSTRACT

The present invention has as an object to provide a solid-state imaging device which makes possible mixing pixels without causing quality deterioration, such as non-uniformity of an image. A VDr (110) controls transfer of charge performed by a column CCD (210), so that: the column CCD (210) sequentially transfers plural packets each representing the charge transferred through successive well regions which are divided by a barrier region; a stand-by period in which the charge transfer in the plural packets suspends for every plural packets is longer than a transfer period in which the charge transfer in the plural packets is performed; two of charge transfer stages working as barrier regions are two charge transfer stages out of four or more charge transfer stages in the stand-by period; and one of neighboring two charge transfer stages works as the barrier region or a well region with a potential inclined in a charge transfer direction, and the other one of the neighboring two charge transfer stages (i) is positioned upstream of the transfer direction of the charge in relation to the one of the charge transfer stages, (ii) has no potential inclined in the transfer direction of the charge, (iii) and works as a barrier region having a potential higher than the one of the charge transfer stages in the stand-by period.

### TECHNICAL FIELD

The present invention relates to solid-state imaging devices and, in particular, to a Charge Coupled Device (CCD) solid-state imaging device.

### BACKGROUND ART

A typical solid-state imaging device for imaging devices in video cameras and digital still cameras employs a CCD solid-state imaging device. In the CCD solid-state imaging device, a photo diode generates signal charge out of incident light. Then, the signal charge is read to a column CCD, and the column CCD and a row CCD transfer the signal charge to a charge detecting unit (FD unit).

On the CCD solid-state imaging device, Patent Reference 1 for example discloses a technique to mix pixels for improving an image signal in output speed. The CCD solid-state imaging device includes a transferring unit placed on the last stage of the column CCD, the transferring unit which can control the drive independently from column CCDs on the other columns. Hence, the reading of the signal charge from the column CCD to the row CCD is independently controlled for each column, and signal charge of pixels in a row direction is mixed in the row CCD.
Patent Reference 1: Japanese Unexamined Patent Application Publication No. 2004-180284

### DISCLOSURE OF INVENTION

### Problems that Invention is to Solve

Reduction of a CCD area to realize a smaller size of solid-state imaging device develops a transfer degradation spot in a barrier region of a CCD due to a finished dimension of the CCD gate and subtle variation in impurity profile and gate insulation film. In the case of a six-phase-drive column CCD, for example, when a low-level driving pulse is applied to two neighboring driving electrodes V5 and V6 as shown in the potential distribution of the column CCD in FIG. 1(a), a transfer degradation spot (“A” in FIG. 1(a)) occurs in the barrier regions below the two driving electrodes V5 and V6. In the transfer degradation spot, part of a column-transferred packet (a signal charge transferred in successive well regions divided for each barrier region) 400 is trapped. When the column transfer is suspended, the trapped signal charge is released and added to a packet accumulated in the well regions. Subject to the above effect, the solid-state imaging device in Patent Reference 1 causes variation in an amount of charge of plural packets to be transferred. The variation is detailed with reference to a variation diagram of the potential distribution of the column CCD shown in FIG. 2.

In the case of the solid-state imaging device described in Patent Reference 1, the pixel mixing (in the case of mixing nine pixels) involves transferring three plural packets (signal charge for three pixels) instead of one packet (signal charge for one pixel) to the row CCD, followed by a suspension period in which the column transfer is suspended (FIG. 2(a)). Here, the signal charge has been trapped at the transfer degradation spot (“A” in FIG. 2) of the barrier region between the stages. The trapped signal charge is added to the packet accumulated in the well regions (FIG. 2(b)) while the column transfer is being suspended. Upon resuming the column transfer, part of the next packet passing through the transfer degradation spot is trapped thereby (FIG. 2(c)). Since the trapped signal charge tends to be readily released when transfer is suspended longer than a time required for transferring the packet for a stage (a time required for a change of a state from FIG. 2(d) to FIG. 2(e)), the next two plural packets are successively column-transferred, almost free from the effect of the transfer degradation spot (FIG. 2(d) to FIG. 2(e)). Thus, increase in the amount of signal charge is observed in some packets, and decrease in the amount of signal charge is observed in other packets. These cause variation in the amount of the signal charge to be transferred. The variation in the amount of the signal charge results in quality deterioration, such as non-uniformity of an image.

The present invention is conceived in view of the above problems and has as an object to provide a solid-state imaging device which makes possible mixing pixels without causing quality deterioration, such as non-uniformity of an image.

### Means to Solve the Problems

In order to achieve the above object, an aspect of a solid-state imaging device in the present invention includes: photoelectric converting elements which are two-dimensionally arranged; column transferring units each of which transfers charge in a column direction, the charge being generated by each of the photoelectric converting elements; a row transferring unit which transfers the charge in a row direction, the charge being transferred by the column transferring units; and a transfer control unit which controls the charge transfer performed by the column transferring units, wherein each of the column transfer units includes four or more charge transfer stages each of which works as a barrier region or a well region, depending on an applied voltage, each of the charge transfer stages includes a first charge transfer stage having a potential inclined in a charge transfer direction, and a second charge transfer stage having no inclined potential, and the transfer control unit controls the charge transfer so that: (i) the column transfer unit sequentially transfers a plurality of packets each representing the charge transferred through successive well regions including the well region, the successive well regions being divided by the barrier region; (ii) a stand-by period in which the charge transfer in the plurality of packets is suspended longer than a transfer period in which the charge transfer for each of the plurality of packets is performed; and (iii) two of the four or more charge transfer stages are neighboring two charge transfer stages each working as the barrier region in the stand-by period, and one of the neighboring two charge transfer stages is the first charge transfer stage and an other one is the second charge transfer stage positioned upstream in the charge transfer direction in relation to the first charge transfer stage.

Hence, signal charge trapped at the transfer degradation spot is added in the stand-by period to the well region positioned upstream of the transfer direction of the charge in relation to the stages working as the barrier regions. As a result, even though the amount of signal charge increases in some packets in the stand-by period, resume of the charge transfer causes the signal charge to be trapped again at the transfer degradation spot. The amount of signal charge decreases as much as the increased amount of the signal charge. Hence the solid-state imaging device in the present invention makes possible mixing pixels without causing quality deterioration, such as non-uniformity of an image, since variation caused by the signal charge trapped at the transfer deterioration spot is not observed in the amount of the signal charge to be transferred as seen on the solid-state imaging device described in Patent Reference 1.

Further, the first charge transfer stage works as the well region or the barrier region having the potential inclined in the charge transfer direction. As a result, signal charge is difficult to be trapped or is not trapped at all at the transfer degradation spot, which further reduces variation of the amount of signal charge.

Here, the column transferring unit may include four or more electrodes each of which is provided on, for applying a voltage to, a corresponding one of the four or more charge transfer stages. The four or more electrodes may include, in the charge transfer direction, a relatively long electrode and a relatively short electrode. The first charge transfer stage may have the relatively long electrode, and the second charge transfer stage may have the relatively short electrode.

This minimizes the increase in area of the well region in the charge transfer, resulting in minimizing the increase in dark current.

Further, the transfer control unit may control the charge transfer performed by the column transferring unit so that, in the stand-by period, a charge transfer stage works as the barrier region, followed by working as the well region and then standing by, the charge transfer stage being located between the row transferring unit and a charge transfer stage which is closest to the row transferring unit and works as the barrier region.

Since this can increase the difference of electric potentials between the row transferring units and the last stage of the column transferring unit, a packet can be transferred to the row transferring unit without leaving untransferred charge, resulting in preventing deterioration of transfer efficiency between the row transferring unit and the column transferring unit.

Moreover, another aspect of a solid-state imaging device in the present invention may include: photoelectric converting elements which are two-dimensionally arranged; column transferring units each of which is transfers charge in a column direction, the charge being generated by each of the photoelectric converting elements; a row transfer unit which transfers the charge in a row direction, the charge being transferred by the column transferring units; and a transfer control unit which controls the charge transfer performed by the column transferring units, wherein each of the column transfer units includes four or more charge transfer stages which work as a barrier region or a well region, depending on an applied voltage, and the transfer control unit controls the charge transfer so that: (i) the column transfer unit sequentially transfers a plurality of packets each representing the charge transferred through successive well regions including the well region, the successive well regions being divided by the barrier region; (ii) a stand-by period in which the charge transfer in the plurality of packets is suspended by discontinuation of the plurality of packets is longer than a transfer period in which the charge transfer for each of the plurality of packets is performed; and (iii) one of the four or more charge transfer stages works as the barrier region in the stand-by period.

This enables the charge transfer to be controlled, so that one charge transfer stage works as the barrier region in the stand-by period; namely, one gate barrier. Since this intensifies the fringe electric field, which causes the signal charge trapped at the transfer degradation spot to be released in a time shorter than a time required to transfer the packet for one stage. Thus, no variation is observed in the amount of signal charge to be transferred, as seen in the solid-state imaging device described in Patent Reference 1. As a result, pixel mixing in the row CCD is possible without causing quality deterioration, such as non-uniformity of an image.

Here, the column transferring unit may include four or more electrodes each of which is provided on, for applying a voltage to, a corresponding one of the four or more charge transfer stages. The four or more electrodes may include, in the charge transfer direction, a relatively long electrode and a relatively short electrode. The transfer control unit may control the charge transfer performed by the column transferring unit, so that, in the stand-by period, the one of the four or more charge transfer stages working as the barrier region is a charge transfer stage having the relatively long electrode.

This minimizes the increase in area of the well region in the charge transfer, resulting in minimizing the increase in dark current.

In addition, the charge transfer stage having the relatively long electrode may work as the well region or the barrier region which has a potential inclined in a charge transfer direction.

As a result, signal charge is difficult to be trapped or is not trapped at all at the transfer degradation spot, which further reduces variation of the amount of signal charge.

Further, the transfer control unit may control the charge transfer performed by the column transferring unit so that, in the stand-by period, a charge transfer stage works as the barrier region, followed by working as the well region, the charge transfer stage being located between the row transferring unit and a charge transfer stage, out of the four or more charge transfer stages, which is closest to the row transferring unit and works as the barrier region.

Since this can increase the difference of electric potentials between the row transferring units and the last stage of the column transferring unit, a packet can be transferred to the row transferring unit without leaving untransferred charge, resulting in preventing deterioration of transfer efficiency between the row transferring unit and the column transferring unit.

### Effects of the Invention

The present invention can realize a solid-state imaging device which makes possible mixing pixels without causing quality deterioration, such as non-uniformity of an image.

### BRIEF DESCRIPTION OF DRAWINGS

FIG. 1 shows how a packet is transferred in a column CCD having a transfer degradation spot.

FIG. 2 shows how the packet is transferred in the column CCD having the transfer degradation spot.

FIG. 3 shows a schematic structure of a camera in accordance with an embodiment of the present invention.

FIG. 4A illustrates a detailed structure of a solid-state imaging element in accordance with the embodiment.

FIG. 4B shows a schematic structure of a sorting and transferring unit.

FIG. 5 is a cross-sectional view showing a structure of a column CCD, on a second column, in accordance with the embodiment.

FIG. 6 is a variation diagram of potential distribution showing a method for transferring a packet in the column CCD, on the second column, in accordance with the embodiment.

FIG. 7 shows how a packet is transferred by a column CCD having a transfer degradation spot.

FIG. 8 is a variation diagram of potential distribution showing a method for transferring a packet in the column CCD, on the second column, in accordance with a modification of the embodiment.

FIG. 9 is a variation diagram of the potential distribution showing the method for transferring the packet in the column CCD, on the second column, in accordance with the embodiment.

FIG. 10 is a variation diagram of the potential distribution showing the method for transferring the packet in the column CCD, on the second column, in accordance with the modification of the embodiment.

FIG. 11 shows how a packet is transferred in a column CCD having a transfer degradation spot.

### NUMERICAL REFERENCES

100 Solid-state imaging element

110 Clock driver (VDr)

120 Preprocessing unit (CDS/AGC)

130 Digital signal processing unit (DSP)

140 Timing generator (TG)

200 Photo diode

210 Column CCD

220 Row CCD

230 Sorting and transferring unit

240 Imaging unit

250 Charge detecting unit

300 Substrate

310, 320, and 330 Impurity region

400 Packet

### BEST MODE FOR CARRYING OUT THE INVENTION

Hereinafter, a solid-state imaging device in accordance with an embodiment of the present invention shall be described with reference to the drawings.

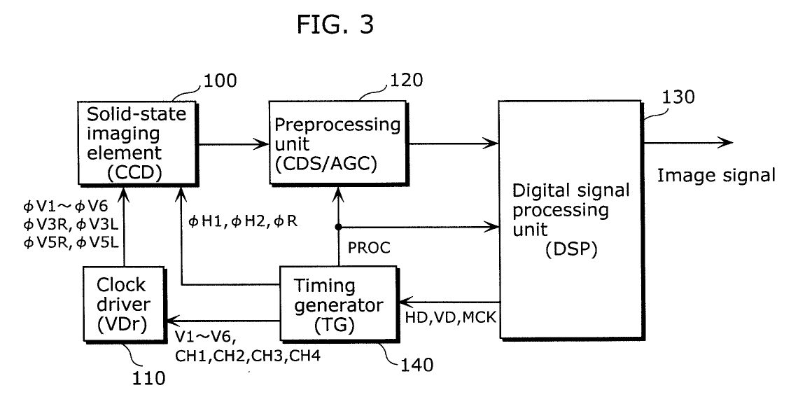

FIG. 3 shows a schematic structure of an imaging device (camera) in accordance with the embodiment.

This camera includes a CCD solid-state imaging element 100, a clock driver (VDr) 110, a preprocessing unit (CDS/AGC) 120, a digital signal processing unit 130, and a timing generator (TG) 140. The solid-state imaging element 100 photoelectric-converts incident light to generate a signal charge, and transfers the signal charge. The preprocessing unit 120 performs CDS (Correlated Double Sampling) and ADC (Analog-Digital Conversion). The DSP 130 performs image interpolation and luminance and color-difference processing to provide an image signal. It is noted that the solid-state imaging element 100, the VDr 110, and the TG 140 are included in the solid-state imaging device in the present invention.

The VDr 110, exemplifying a transfer control unit of the present invention, controls transfer of charge performed by a column CCD, so that: the column CCD sequentially transfers plural packets; a stand-by period in which the charge transfer in the plural packets suspends for every plural packets is longer than a transfer period in which the charge transfer in the plural packets is performed; two of charge transfer stages working as barrier regions are neighboring two charge transfer stages out of four or more charge transfer stages in the stand-by period; and one of the neighboring two charge transfer stages works as the barrier region or a well region with a potential inclined in a charge transfer direction, and the other one of the neighboring two charge transfer stages (i) is positioned upstream of the transfer direction of the charge in relation to the one of the charge transfer stages, (ii) has no potential inclined in the transfer direction of the charge, (iii) and works as a barrier region having a potential higher than the one of the charge transfer stages in the stand-by period. Specifically, the VDr 110: generates driving pulses φV1 to φV6, φV3R, φV3L, φV5R, and φV5L out of logic signals V1 to V6 and CH1 to CH4 provided from the TG 140; supplies the driving pulses φV1 to φV6, φV3R, φV3L, φV5R, and φV5L to the column CCD in the solid-state imaging element 100; and controls transfer of charge performed by the column CCD. The driving pulses φV1 to φV6, φV3R, φV3L, φV5R, and φV5L have three electric potentials; namely, a high-level electric potential V_{H}, a middle-level electric potential V_{M} which is lower than the electric potential V_{H}, and a low-level electric potential V_{L} which is lower than the electric potential V_{M}. For example, the driving pulses φV1 to φV6 are assumed to have three electric potentials; namely, 12V as the electric potential V_{H}, 0V as the electric potential V_{M}, and −6V as the electric potential V_{L}.

Receiving each of pulses of a row synchronization signal HD, a column synchronization signal VD, and a clock signal MCK from DSP 130, the TG 140 generates driving pulses φH1, φH2, and φR, and the logic signals V1 to V6 and CH1 to CH4, as well as provides a signal processing pulse PROC to the preprocessing unit 120 and the DSP 130.

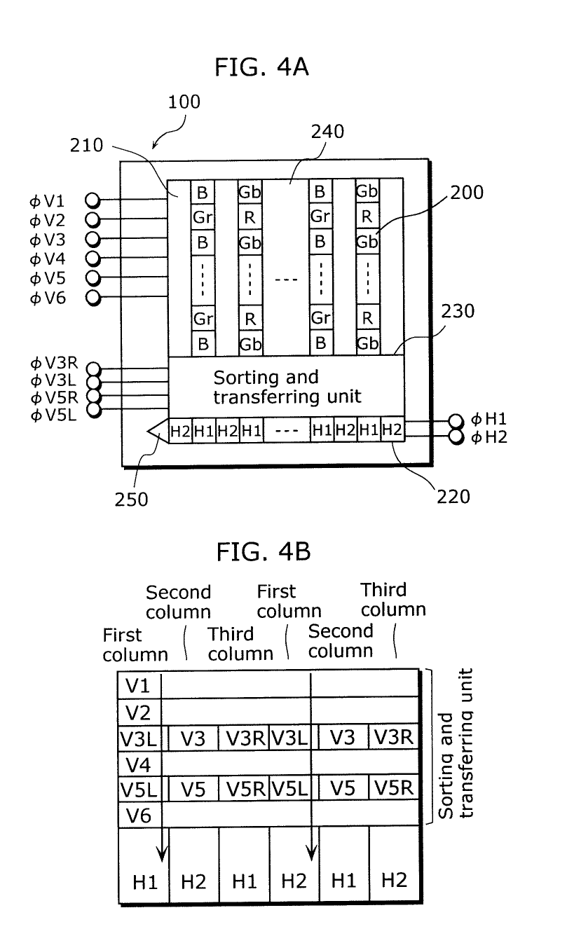

FIGS. 4A and 4B show schematic structures of the solid-state imaging element 100 and a sorting and transferring unit 230, respectively.

As shown in FIG. 4A, the solid-state imaging element 100 includes photo diodes 200, column CCDs 210, a row CCD 220 and a charge detecting unit 250.

Each of the photo diodes 200, exemplifying a photoelectric converting element of the present invention, is arranged in two dimension (in a matrix) in order to correspond to respective pixels. Color filters each representing one of three colors; namely red (R), green (G), and blue (B), are placed on the associated photo diodes 200.

Each of the column CCDs 210, exemplifying a column transferring unit in the present invention, includes a CCD having driving electrodes V1 to V6, V3R, V3L, V5R, and V5L. The column CCDs 210 transfer, in a column direction, signal charge generated by the photo diodes 200, according to application of the driving pulses φV1 to φV6, φV3R, φV3L, φV5R, and φV5L.

The row CCD 220, exemplifying a row transferring unit, includes a CCD having driving electrodes H1 and H2, and transfers, in a row direction, the signal charge transferred by the column CCDs 210, according to application of driving pulses φH1 and φH2.

On the last stage, of the column CCDs 210, closest to the row CCD 220 is formed the sorting and transferring unit 230 for independently controlling reading of the signal charge from the column CCDs 210 to the row CCD 220 for each column. Here, the last stage on which the sorting and transferring unit 230 is formed is provided between an imaging unit 240 where photo diodes 200 and the column CCDs 210 are formed and the row CCD 220.

As shown in FIG. 4B, the sorting and transferring unit 230 employs the same electrode structure for every third column. Specifically, the sorting and transferring unit 230 in the column CCD 210 on the first column has the driving electrodes V1, V2, V3L, V4, V5L, and V6. The sorting and transferring unit 230 in the column CCD 210 on the second column has the driving electrodes V1 to V6. The sorting and transferring unit 230 in the column CCD 210 on the third column has the driving electrodes V1, V2, V3R, V4, V5R and V6. Here, the driving electrodes V1, V2, V4, and V6 are common electrodes over all the columns. Each of the driving electrodes V3, V3R, V3L, V5, V5R, and V5L is independent and separated in an island for each column.

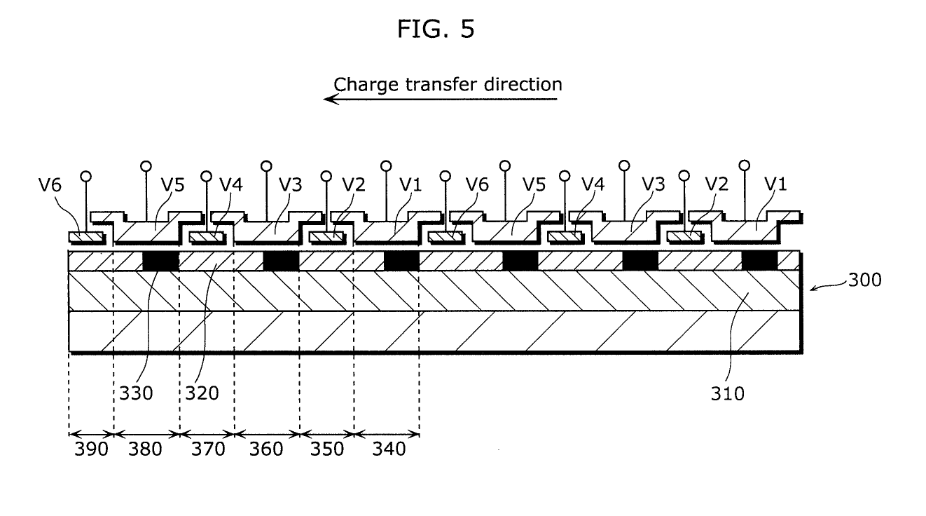

FIG. 5 is a cross-sectional view showing a structure of the column CCD 210 on the second column.

Neighboring two driving electrodes of the column CCD 210 are formed in a two-layer structure in which a portion of the electrodes are overlapping. Here, one of the electrodes making up the two-layer structure is relatively longer than the other in a charge transfer direction. Specifically, the driving electrodes V1, V3, and V5 are longer than the driving electrodes V2, V4, and V6 in the charge transfer direction. That providing each of the driving electrodes V1, V3, and V5 to be provided on a reading path of the signal charge of the photo diode 200 enlarges an area of a transfer electrode to which the electric potential V_{H}; that is a reading voltage of the signal charge of the photo diode 200, is applied. As a result, a reading channel width required for reading the signal charge can be secured even in the case where the pixels are refined.

Positioned below the driving electrodes V1 to V6 is a p-type substrate 300. In the substrate 300, an n-type impurity region 310 is formed as a portion of the column CCD 210. In the impurity region 310, that injecting an impurity into the impurity region 310 to form a step-wise impurity concentration forms an n⁺type impurity region 320 and an n⁻type impurity region 330 respectively greater and smaller than the impurity region 310 in concentration. The impurity regions form periodic six charge transfer stages acting as a barrier region or a well region of the potentials according to application of voltages to the driving electrodes V1 to V6. Specifically, the six charge transfer stages include a first charge transfer stage 340 having the driving electrode V1, a second charge transfer stage 350 having the driving electrode V2, a third charge transfer stage 360 having the driving electrode V3, a forth charge transfer stage 370 having the driving electrode V4, a fifth charge transfer stage 380 having the driving electrode V5, and a sixth charge transfer stage 390 having the driving electrode V6. Hence, these impurity regions work as a column charge transfer path (VCCD) through which the signal charge is transferred.

Regions each having a different impurity concentration; namely the impurity regions 320 and 330, are disposed on associated impurity regions 310 below the driving electrodes V1, V3, and V5. Thus, each of the first charge transfer stage 340, the third charge transfer stage 360, and the fifth charge transfer stage 380 acts as a barrier region or a well region with the potentials inclined in a charge transfer direction.

It is noted that each of the column CCDs 210 on the first and the third columns has any one of the driving electrodes V3 replaced with either the driving electrode V3R or V3L, and has any one of the driving electrodes V5 replaced with either the driving electrode V5R or V5L; however, structures of the column CCDs 210 on the first and the third columns are similar to that shown in FIG. 5.

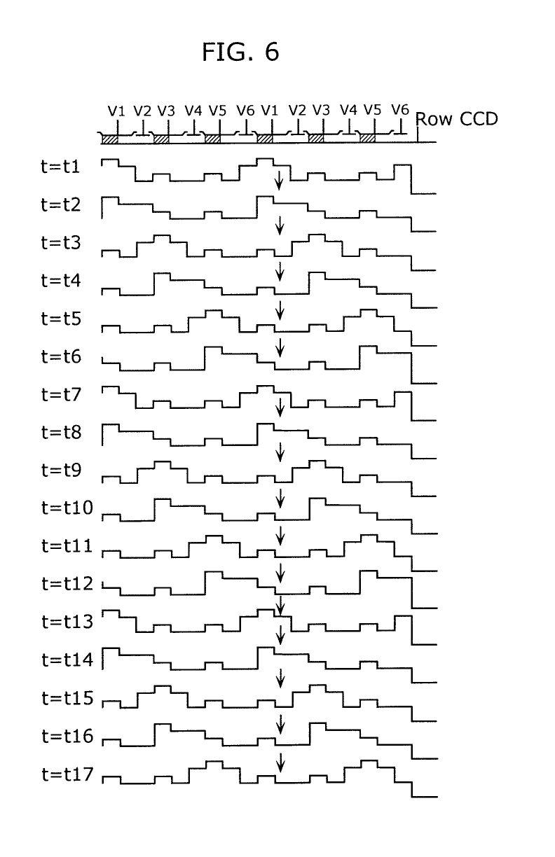

FIG. 6 is a variation diagram (a variation diagram of potential distribution in the column CCD 210 of the second column) of potential distribution showing a method for transferring a packet in the column CCD 210 having the above structure. It is noted that the method exemplifies a method for driving the solid-state imaging device in the present invention.

Between times t1 and t6, one of plural packets in the column CCD 210 on the second column is transferred to the row CCD 220. Then, not shown, the transferred packet is again transferred in a row direction for two pixels, and one of plural packets in the column CCD 210 on the third column is transferred to the row CCD 220. The transferred packet is again transferred in a row direction for two pixels, and one of plural packets in the column CCD 210 on the first column is transferred to the row CCD 220.

Similar to the above, between times t7 and t12, and between t13 and t17, one of plural packets in the column CCD 210 on the second column is transferred to the row CCD 220, followed by transferring one packet each in the column CCDs 210 on the third and the first columns to the row CCD 220. Accordingly, three packets each in the column CCD 210 on each column are sequentially transferred to the row CCD 220.

At the time t17, the middle-level electric potential V_{M} is applied to the driving electrode V6, the column CCD 210 is controlled so that charge transfer stages working as barrier regions are the neighboring two stages out of the six charge transfer stages, and then the column transfer is suspended. One of the neighboring two charge transfer stages (stage corresponding to the driving electrode V5) works as a barrier region with the potential inclined in the transfer direction of the charge. The other one of the neighboring two stages (stage corresponding to the driving electrode V4) is positioned upstream of the transfer direction of the charge in relation to the charge transfer stage (corresponding to the driving electrode V5), has no potential inclined in the transfer direction of the charge at a stand-by period, and works as a barrier region having a potential higher than the charge transfer stage (corresponding to the driving electrode V5). The stand-by period in which the charge transfer is suspended; that is a stand-by period in which the charge transfer suspended for every third packet, is longer than a transfer period (period between the times t1 and t6, between the times t7 and t12, and between t13 and t17) in which the charge is transferred in one packet. Then, the plural packets in the row CCD 220 are transferred to the charge detecting unit 250. It is noted that each of the column CCDs 210 on the third and the first columns has the charge transfer stages, working as the barrier regions in the stand-by period, designated to be neighboring two stages out of the six charge transfer stages.

In order to transfer the plural packets as described above, each driving pulse is applied to the column CCDs 210 and the row CCD 220 to drive the Column CCDs 210 and the row CCD 220. This causes in the CCD 220 the signal charge for three pixels to be mixed in a row direction.

As described above, the camera in accordance with the embodiment includes two charge transfer stages, working as barrier regions in a stand-by period, designated to be neighboring two stages out of six charge transfer stages. Then, one of the neighboring two charge transfer stages (stage corresponding to the driving electrode V5) works as a barrier region or a well region with the potential inclined in the transfer direction of the charge. The other one of the neighboring two charge transfer stages (stage corresponding to the driving electrode V4) is (i) positioned upstream of the transfer direction of the charge in relation to the charge transfer stage (corresponding to the driving electrode V5), (ii) has no potential inclined in the transfer direction of the charge, (iii) and works as a barrier region having a potential higher than the charge transfer stage (corresponding to the driving electrode V5) at a stand-by period. Hence signal charge trapped at the transfer degradation spot is added in the stand-by period to the well regions of the charge transfer stages (stages corresponding to the driving electrodes V1, V2, V3, and V6) positioned upstream of the transfer direction of the charge in relation to the stages (stages corresponding to the driving electrodes V4 and V5) working as the barrier regions. As a result, even though the amount of signal charge increases in some plural packets in the stand-by period, resume of the charge transfer causes the increased signal charge to be trapped again at the transfer degradation spot. Thus, the amount of the signal charge decreases as much as the increased amount of the signal charge. This prevents variation in an amount of signal charge to be transferred caused by the trapped signal charge at the transfer degradation spot between the stages, as the solid-state imaging device described in Patent Reference 1 suffers. Hence the solid-state imaging device in the present invention makes possible mixing pixels in the row CCD without causing quality deterioration, such as non-uniformity of an image since variation caused by the signal charge trapped at the transfer deterioration spot is not observed in the amount of the signal charge to be transferred as seen on the solid-state imaging device described in Patent Reference 1.

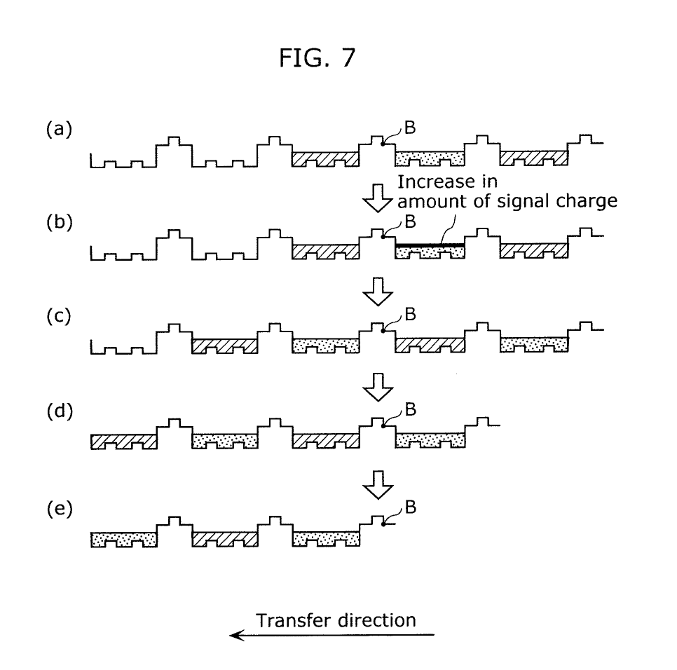

Specifically, as shown in FIG. 7, the signal charge trapped at the transfer degradation spot (B in FIG. 7) in the barrier region is added to plural packets accumulated in the well region (FIGS. 7(a) and 7(b)). Once the column transfer is resumed, the signal charge of the plural packets, with the trapped signal charge added, passing the transfer degradation spot are trapped at the transfer degradation spot (FIG. 7(c)). Since the trapped signal charge is easily released when the transfer is suspended longer than the time required for transferring the plural packets for one stage (time required to change the state from FIG. 7(d) to FIG. 7(e)), the next two plural packets are sequentially transferred in a column direction, suffering almost no effect from the transfer degradation spot (FIGS. 7(d) and 7(e)). Thus, the amount of signal charge increases and decreases as much as the increased amount for some of the plural packets, which causes no variation in the amount of signal charge to be transferred.

In accordance with the camera of the embodiment, moreover, the transfer operation is suspended, following transfer of plural packets. Once the transfer operation is resumed, no variation is observed in the amount of signal charge to be transferred due to the above reasons. This allows the camera to stabilize an image and zoom in without causing deterioration, such as non-uniformity of an image.

Further, in an Electric Image Stabilizer (EIS) solid-state imaging device, the transfer operation is suspended, following transfer of plural packets. Thus, the use of the solid-state imaging device in accordance with the embodiment of the present invention and a method for driving thereof for the EIS solid-state imaging device makes possible preventing quality deterioration, such as non-uniformity of an image, on the EIS solid-state imaging device.

As a potential step below the driving electrode V5 in FIG. 6 shows, the camera in accordance with the embodiment causes in the stand-by period a charge transfer stage having a driving electrode (the driving electrode V5) which is long in a charge transfer direction, as well as a charge transfer stage having a driving electrode which is short in a charge transfer direction, to work as a barrier region. This minimizes the increase in area of the well region, resulting in minimizing the increase in dark current.

Further, in accordance with the camera in the embodiment, impurity concentration profile is formed on the charge transfer stage working as a barrier region in the stand-by period. In the impurity concentration profile, the potential decreases toward a neighboring charge transfer stage. Thus, the charge transfer stage works as the well region or the barrier region having a potential inclined in the charge transfer direction. As a result, signal charge is difficult to be trapped or are not trapped at all, which further reduces variation of the amount of signal charge.

In addition, the camera in accordance with the embodiment does not discard the signal charge in pixel mixing, and thus can obtain an image signal having high sensitivity. Further, centers of gravity in mixed pixels groups in the row CCD keep equal distance each other, which makes possible obtaining an image signal with little moire or few aliases. Thus, the camera in the embodiment can provide a high-quality image signal at a high speed without moire or an alias.

(Modification)

Described here is a modification in accordance with the embodiment. In the modification, the VDr 110 controls transfer of charge performed by the column CCD so that: the column CCD sequentially transfers plural packets; the stand-by period in which the charge transfer in the plural packets is suspended for every plural packets is longer than the transfer period in which the charge transfer in the plural packets is performed; and a charge transfer stage working as a barrier region is designated as one of four or more charge transfer stages in the stand-by period.

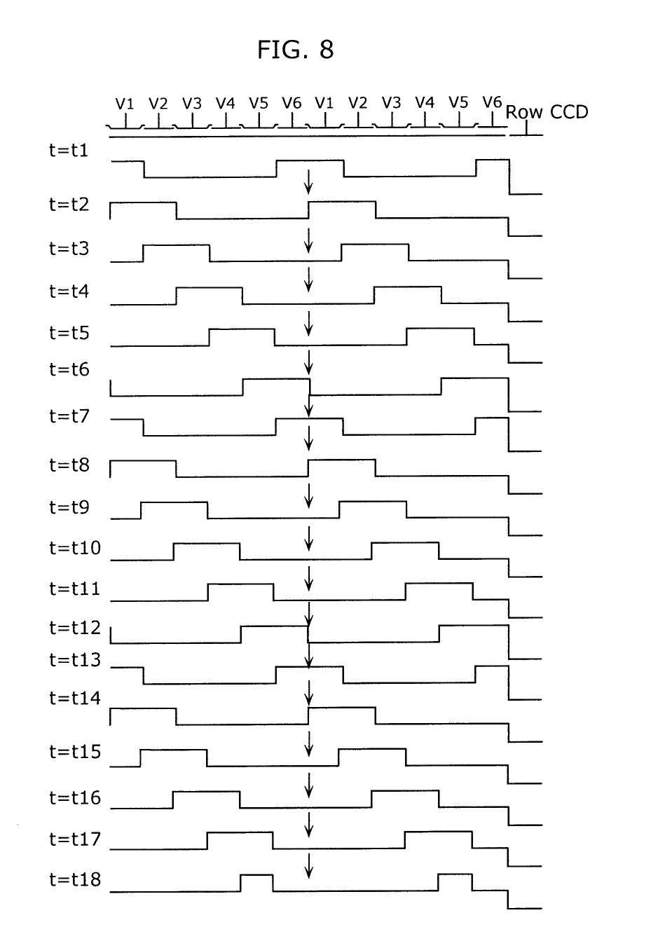

FIG. 8 is a variation diagram (a variation diagram of potential distribution in the column CCD 210 on the second column) of potential distribution showing a method for transferring a packet in the column CCD 210 in solid-state imaging device according to the modification. It is noted that the method exemplifies a method for driving the solid-state imaging device in the present invention.

Between times t1 and t6, one of plural packets in the column CCD 210 on the second column is transferred to the row CCD 220. Then, not shown, the transferred packet is again transferred in a row direction for two pixels, and one of plural packets in the column CCD 210 on the third column is transferred to the row CCD 220. The transferred packet is again transferred in a row direction for two pixels, and one of plural packets in the column CCD on the first column is transferred to the row CCD 220.

Similar to the above, between times t7 and t12, and between t13 and t17, one of plural packets in the column CCD 210 on the second column is transferred, followed by transferring one packet each in the column CCDs 210 on the third and the first columns. Accordingly, three of the plural packets in the column CCD 210 on each column are sequentially transferred to the row CCD 220.

At a time t18, the middle-level voltage V_{M} is applied to the driving electrode V6, the column CCD 210 is controlled so that a charge transfer stage to work as a barrier region is designated as one of the six charge transfer stages (the stage corresponding to the driving electrode V5), and then the column transfer is suspended. The stand-by period in which the column transfer is suspended; namely a stand-by period in which the charge transfer is suspended for transferring every three plural packets, is longer than a transfer period (period between times t1 and t6, between times t7 and t12, or between times t13 and t17) in which charge is transferred in one packet. Then, plural packets in the row CCD 220 are transferred to the charge detecting unit 250. It is noted that each of the column CCDs 210 on the third and the first columns has the charge transfer stage, working as the barrier region in the stand-by period, designated to be one of the stages out of the six charge transfer stages.

In order to transfer the plural packets as described above, each driving pulse is applied to the column CCDs 210 and the row CCD 220 to drive the column CCDs 210 and the row CCD 220. This causes the signal charge for three pixels to be mixed in a row direction in the row CCD 220.

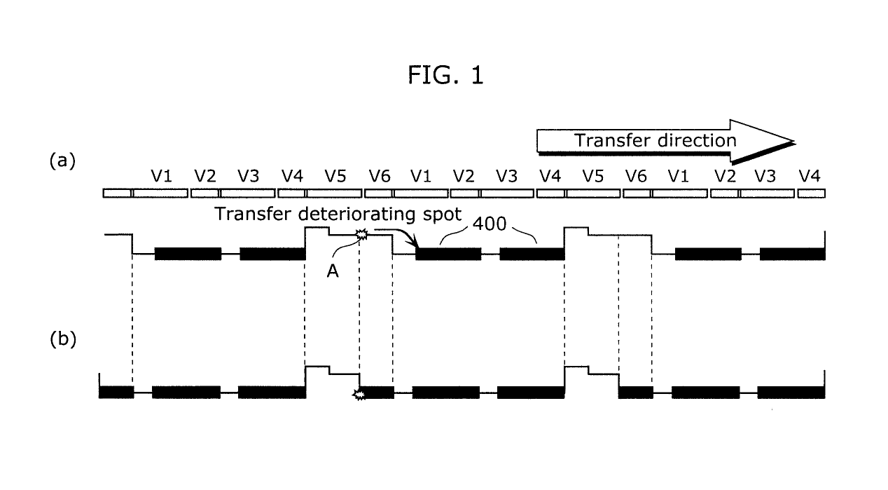

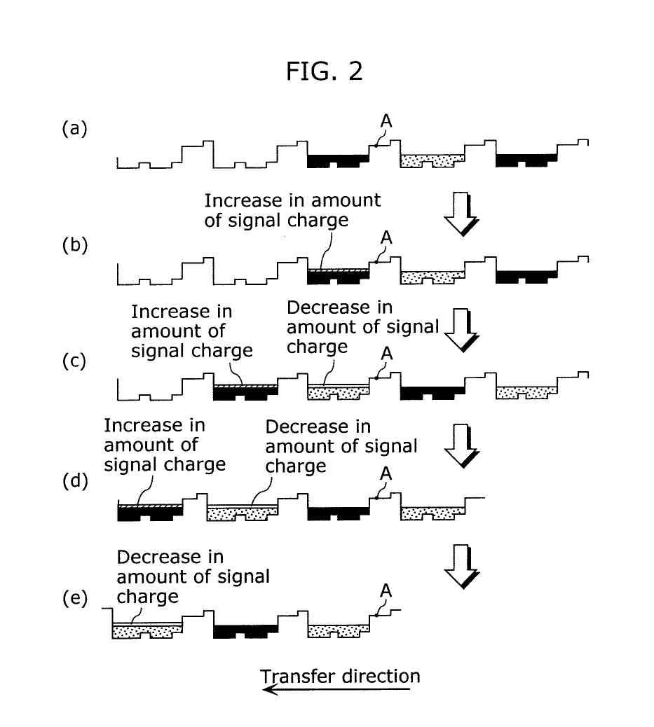

In the solid-state imaging device according to the modification as described above, as shown in FIG. 1(b), a charge transfer stage working as a barrier region in the stand-by period is designated as one of the six charge transfer stages (a stage corresponding to the driving electrode V6). This intensifies the fringe electric field, which causes the signal charge trapped at the transfer degradation spot to be released in a short time; that is a time shorter than a time required to transfer one packet for one stage. Thus, no variation is observed in the amount of signal charge to be transferred, as seen in the solid-state imaging device described in Patent Reference 1. As a result, pixel mixing in the row CCD is possible without causing quality deterioration, such as non-uniformity of an image.

According to the solid-state imaging device in the modification, FIG. 1(b) shows that the charge transfer stage working as a barrier region in the stand-by period is designated as one of the six charge transfer stages (the stage corresponding to the driving electrode V6). This (i) intensifies the fringe electric field, which causes the signal charge trapped at the transfer degradation spot to be released in a short time; that is a time shorter than a time required to transfer one packet for one stage, and (ii) causes the transfer operation to be suspended after the plural packets are transferred. Thus, no variation is observed in the amount of signal charge to be transferred. This allows the solid-state imaging device to correct image-shaking and electrically zoom in without causing deterioration, such as non-uniformity of an image

Described above is the solid-state imaging device in the present invention in accordance with the embodiment; meanwhile, although only an exemplary embodiment of this invention has been described in detail above, those skilled in the art will readily appreciate that many modifications are possible in the exemplary embodiment without materially departing from the novel teachings and advantages of this invention. Accordingly, all such modifications are intended to be included within the scope of this invention.

In accordance with the camera described in the embodiment, for example, the charge may be transferred, so that a charge transfer stage, out of charge transfer stages working as barrier regions in a stand-by period, located between the charge transfer stage positioned closest to the row CCD and the row CCD may work as a well region in the stand-by period after working as the barrier region. Since this can increase the difference of electric potentials between the row CCD and the last stage of the column CCD, one packet can be transferred to the row CCD without leaving untransferred charge, resulting in preventing deterioration of transfer efficiency between the row CCD and the column CCD.

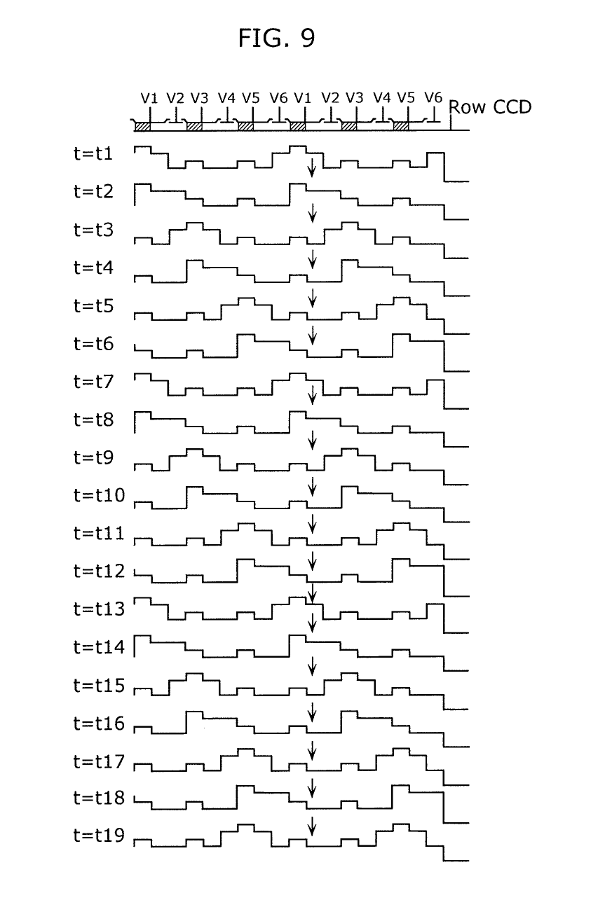

In the above case, the plural packets are transferred according to the variation diagram (the variation diagram of the potential distribution on the column CCD in the second column) of the potential distribution in FIG. 9, for example. This transfer is different from the packet transfer shown in FIG. 6 in that the low-level voltage V_{L} is applied to the driving electrode V6 at the time t18 following the time t17, a charge transfer stage having the driving electrode V6 works as a barrier region or then the middle-level potential V_{M} is again applied to the driving electrode V6 at the time t19 so that the charge transfer stage having the driving electrode V6 works as a well region.

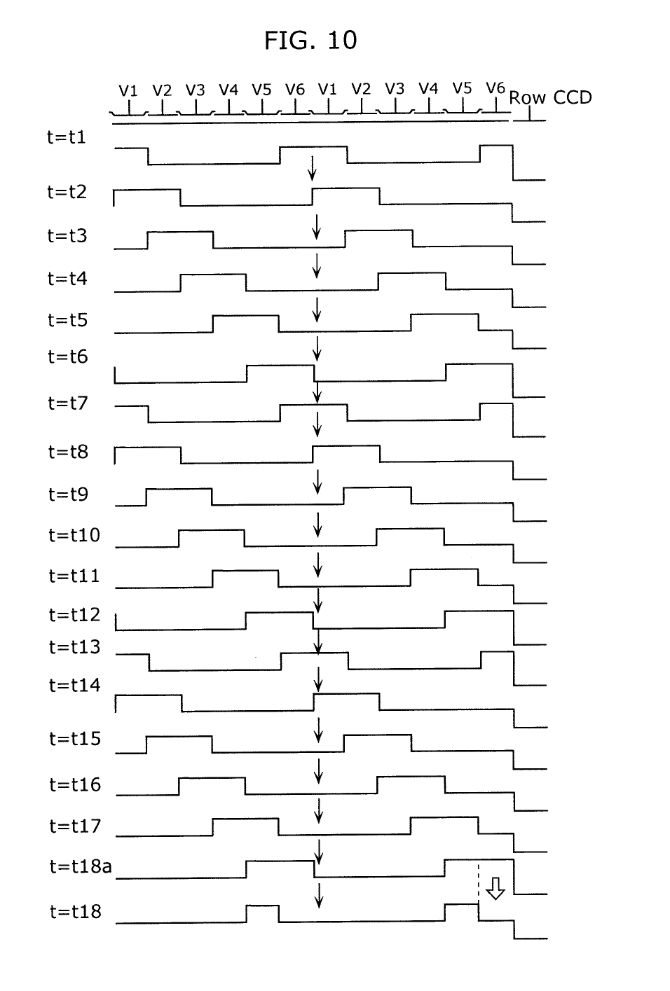

The plural packets are as well transferred according to the variation diagram (the variation diagram of the potential distribution on the column CCD in the second column) of the potential distribution in FIG. 10. This transfer is different from the packet transfer shown in FIG. 8 in that the low-level potential V_{L} is applied to the driving electrode V6 at the time t18a between the times t17 and t18, and the charge transfer stage having the driving electrode V6 works as a barrier region.

Further, in the camera according to the embodiment, one (the stage corresponding to the driving electrode V5) of the neighboring two charge transfer stages, working as barrier regions at the time t17 in FIG. 6, works as a barrier region with the potential increasing step-wise (decreasing step-wise in FIG. 6) toward downstream in a charge transfer direction in relation to the other one of the two charge transfer stages (the stage corresponding to the driving electrode V4). Meanwhile, the one (the stage corresponding to the driving electrode V5) of the two charge transfer stages may work as a barrier region with the potential decreasing step-wise (increasing step-wise in FIG. 6) toward downstream in a charge transfer direction in relation to the other charge transfer stage (the stage corresponding to the driving electrode V4).

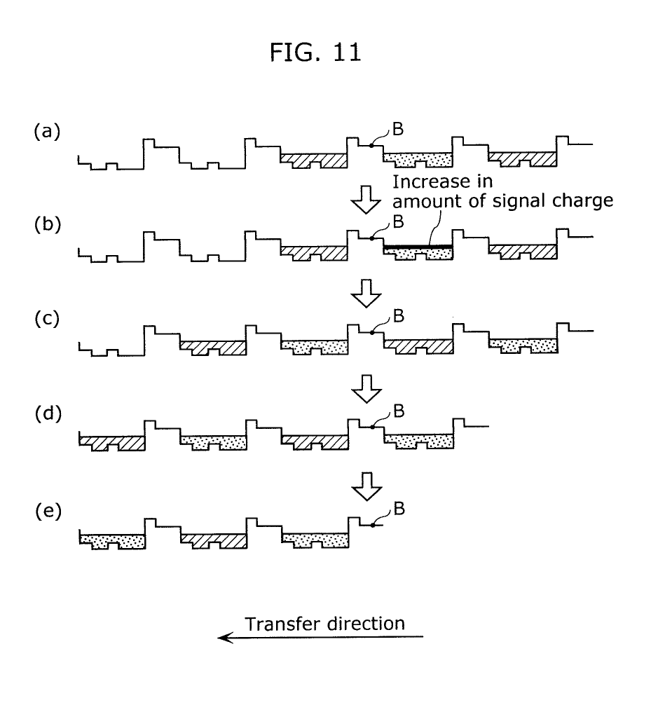

In this case, as shown in FIG. 11, the amount of signal charge increases and decreases as much as the increased amount for some of the plural packets. This causes no variation in the amount of signal charge to be transferred due to the transfer degradation spot (B in FIG. 11) in a barrier region.

In addition, each of the column CCDs is a six-phase-drive column CCD including the transfer electrodes V1 to V6 in accordance with the above embodiment. Meanwhile, the column CCD may be for example four-phase-drive CCD, instead of the six-phase-drive column CCD, in the case where the packet transfer described above is applicable thereto; that is the column transfer CCD has four or more charge transfer stages and driving pulses with four or more phases applied.

Further, in accordance with the embodiment, that injecting an impurity into the impurity region to form the step-wise impurity concentration forms the inclined potential. Meanwhile, the effects of narrow channel widths; that is to increase the widths of the channel where transferring charge in a transfer direction, may be utilized to form the inclined potential.

### INDUSTRIAL APPLICABILITY

The present invention can be utilized for solid-state imaging devices, in particular, for a CCD solid-state imaging device mixing pixels.

1. A solid-state imaging device comprising:
photoelectric converting elements which are two-dimensionally arranged;
column transferring units each of which is configured to transfer charge in a column direction, the charge being generated by each of said photoelectric converting elements;
a row transferring unit configured to transfer the charge in a row direction, the charge being transferred by said column transferring units; and
a transfer control unit configured to control the charge transfer performed by said column transferring units,
wherein each of said column transfer units includes four or more charge transfer stages each of which works as a barrier region or a well region, depending on an applied voltage,
each of said charge transfer stages includes a first charge transfer stage having a potential inclined in a charge transfer direction, and a second charge transfer stage having no inclined potential, and
said transfer control unit is configured to control the charge transfer so that:
(i) said column transfer unit sequentially transfers a plurality of packets each representing the charge transferred through successive well regions including said well region, said successive well regions being divided by said barrier region;
(ii) a stand-by period in which the charge transfer in the plurality of packets is suspended longer than a transfer period in which the charge transfer for each of the plurality of packets is performed; and
(iii) two of said four or more charge transfer stages are neighboring two charge transfer stages each working as said barrier region in the stand-by period, and one of said neighboring two charge transfer stages is said first charge transfer stage and an other one is said second charge transfer stage positioned upstream in the charge transfer direction in relation to said first charge transfer stage.

2. The solid-state imaging device according to claim 1,
wherein, when pixels are being mixed, said column transfer unit is configured to sequentially transfer the plurality of packets representing the charge transferred through said successive well regions being divided by said barrier region.

3. The solid-state imaging device according to claim 1,
wherein, when image-shaking correction and electrical zooming are performed, said column transfer unit is configured to sequentially transfer the plurality of packets representing the charge transferred through said successive well regions being divided by said barrier region.

4. The solid-state imaging device according to claim 1,
wherein said column transferring unit includes four or more electrodes each of which is provided on, for applying a voltage to, a corresponding one of said four or more charge transfer stages,
said four or more electrodes include, in the charge transfer direction, a relatively long electrode and a relatively short electrode, and
said first charge transfer stage has said relatively long electrode, and said second charge transfer stage has said relatively short electrode.

5. The solid-state imaging device according to claim 1,
wherein a step-wise impurity concentration formed by injecting an impurity forms the inclined potential on said first charge transfer stage.

6. The solid-state imaging device according to claim 1,
wherein a use of a narrow channel effect forms the inclined potential on said first charge transfer stage, the narrow channel effect widening a width of a channel of the charge transfer in the charge transfer direction.

7. The solid-state imaging device according to claim 1,
wherein said transfer control unit is configured to control the charge transfer performed by said column transferring unit so that, in the stand-by period, a charge transfer stage works as said barrier region, followed by working as said well region and then standing by, the charge transfer stage being located between said row transferring unit and a charge transfer stage which is closest to said row transferring unit and works as said barrier region.

8. A solid-state imaging device comprising:
photoelectric converting elements which are two-dimensionally arranged;
column transferring units each of which is configured to transfer charge in a column direction, the charge being generated by each of said photoelectric converting elements;
a row transfer unit configured to transfer the charge in a row direction, the charge being transferred by said column transferring units; and
a transfer control unit configured to control the charge transfer performed by said column transferring units,
wherein each of said column transfer units includes four or more charge transfer stages which work as a barrier region or a well region, depending on an applied voltage, and
said transfer control unit is configured to control the charge transfer so that:
(i) said column transfer unit sequentially transfers a plurality of packets each representing the charge transferred through successive well regions including said well region, said successive well regions being divided by said barrier region;
(ii) a stand-by period in which the charge transfer in the plurality of packets is suspended by discontinuation of the plurality of packets is longer than a transfer period in which the charge transfer for each of the plurality of packets is performed; and
(iii) one of said four or more charge transfer stages works as said barrier region in the stand-by period.

9. The solid-state imaging device according to claim 8,
wherein, when pixels are being mixed, said column transfer unit is configured to sequentially transfer the plurality of packets representing the charge transferred through said successive well regions being divided by said barrier region.

10. The solid-state imaging device according to claim 8,
wherein, when image-shaking correction and electrical zooming are performed, said column transfer unit is configured to sequentially transfer said plurality of packets representing the charge transferred through said successive well regions being divided by the barrier region.

11. The solid-state imaging device according to claim 8,
wherein said column transferring unit includes four or more electrodes each of which is provided on, for applying a voltage to, a corresponding one of said four or more charge transfer stages,
said four or more electrodes include, in the charge transfer direction, a relatively long electrode and a relatively short electrode, and
said transfer control unit is configured to control the charge transfer performed by said column transferring unit, so that, in the stand-by period, the one of said four or more charge transfer stages working as said barrier region is a charge transfer stage having said relatively long electrode.

12. The solid-state imaging device according to claim 11,
wherein said charge transfer stage having said relatively long electrode works as said well region or said barrier region which has a potential inclined in a charge transfer direction.

13. The solid-state imaging device according to claim 12,
wherein a step-wise impurity concentration formed by injecting an impurity forms the inclined potential on said charge transfer stage having said relatively long electrode.

14. The solid-state imaging device according to claim 12,
wherein a use of a narrow channel effect forms the inclined potential on said charge transfer having said relatively long electrode, the narrow channel effect widening a width of a channel of the charge transfer in the transfer direction.

15. The solid-state imaging device according to claim 8,
wherein said transfer control unit is configured to control the charge transfer performed by said column transferring unit so that, in the stand-by period, a charge transfer stage works as said barrier region, followed by working as said well region and then standing by, the charge transfer stage being located between said row transferring unit and a charge transfer stage, out of said four or more charge transfer stages, which is closest to said row transferring unit and works as said barrier region.
